(19) United States
(12) Patent Application Publication
(10) Pub. No.: US 2007/0261911 A1
(43) Pub. Date: Nov. 15, 2007

(54) Transducer enclosure

(76) Inventors: George Nichols, Dover, MA (US); Michael Rosen, Weston, MA (US)

Correspondence Address: FISH & RICHARDSON PC, P.O. BOX 1022, MINNEAPOLIS, MN, 55440-1022, US

(21) Appl. No.: 11/433,990

(22) Filed: May 15, 2006

(51) Int. Cl. H05K 5/00

(52) U.S. Cl. 181/150

(57) ABSTRACT

A transducer assembly for a vehicle is described. The transducer assembly includes an enclosure formed from an interior component of the vehicle. The enclosure includes a front section defining an aperture and a rear section defining a volume. The assembly also includes a baffle that is located within a periphery of the aperture so as to form a port between the baffle and the enclosure. A transducer is mechanically coupled to the baffle.

### BACKGROUND OF THE INVENTION

The frequency response of a transducer can be improved by coupling the transducer to an enclosure with a port. This ported enclosure is known as a bass reflex enclosure. The port defines a mass of air and the enclosure volume defines a compliance of air in the volume. The mass of air in the port will resonate with the compliance of air within the enclosure volume when excited by the displacement of a transducer's cone. A ported enclosure can be tuned by considering the volume of air of the enclosure and the mass of air contained in the cross-sectional area and length of the port.

### SUMMARY OF THE INVENTION

In one aspect, the invention is embodied in an enclosure for a transducer. The enclosure includes a front section defining an aperture. A rear section defines a volume. The front and rear sections form a component. A baffle is located within a periphery of the aperture so as to form a port between the baffle and the component.

In one embodiment, the port completely surrounds a periphery of the baffle. In another embodiment, the port at least partially surrounds a periphery of the baffle. The port can be flared. A cross-sectional area of the port can vary along at least a portion of the length of the port to create the flare. The flare can be formed by varying a diameter of the baffle along a depth of the baffle. The flare can be formed by varying the diameter of the component along a length that is adjacent to the baffle. The cross-sectional area of the port can be smoothly-varying or constantly-tapered along at least a portion of the length of the port. The enclosure can also include a plurality of ports disposed around a periphery of baffle. In one configuration, two or more of the plurality of ports have unequal cross-sectional areas.

The rear section of the enclosure can be substantially bowl-shaped. The rear section of the enclosure can be formed from an interior component of the vehicle. The interior component can include a door panel, a package shelf, an instrument panel, a dash board, a seatback, a seat, a visor, a console, headrest, headliner, cargo area lining, or a pillar garnish. In one embodiment, the rear section is fabricated using seamless construction. The integrated component can be fabricated from multiple parts that are integrated together.

The basket of the transducer can be formed from the baffle. The basket of the transducer can be fabricated from plastic material. The front section of the enclosure can also be fabricated from a plastic material. The basket and/or the front section of the enclosure can also be fabricated from a metal, composite or an epoxy material. The transducer can be mechanically coupled to the basket.

In another aspect, the invention is embodied in a transducer assembly for a vehicle. The transducer assembly includes an enclosure formed from an interior component of the vehicle. The enclosure includes a front section that defines an aperture and a rear section that defines a volume. The front and rear sections form an integrated component. The integrated component can be fabricated from multiple parts that are integrated together. A baffle is located within a periphery of the aperture so as to form a port between the baffle and the enclosure. A transducer is mechanically coupled to the baffle.

In one embodiment, the port completely surrounds a periphery of the baffle. In another embodiment, the port partially surrounds a periphery of the baffle. The port can be flared. A cross-sectional area of the port can vary along at least a portion of the length of the port to create at least one flare. The flare can be formed by varying a diameter of the baffle along a depth of the baffle. The flare can be formed by varying the diameter of the enclosure along a length that is adjacent to the baffle. A cross-sectional area of the port can be smoothly-varying or constantly-tapered along at least a portion of the length of the port.

The enclosure can include a plurality of ports disposed around a periphery of the baffle. Two or more of the ports can have unequal cross-sectional areas.

The rear section of the enclosure can be substantially bowl-shaped. The rear section of the enclosure can be formed from an interior component of the vehicle. The interior component can include a door panel, a package shelf, an instrument panel, a dash board, a seatback, a seat, a visor, a console, headrest, headliner, cargo area lining, or a pillar garnish. In one embodiment, the interior component is fabricated using seamless construction.

The basket of the transducer can be formed from the baffle. The basket of the transducer can be fabricated from plastic material. The front section of the enclosure can also be fabricated from a plastic material. The basket and/or the front section of the enclosure can also be fabricated from a metal or an epoxy material. The baffle can be integrated with the enclosure.

In another aspect, the invention is embodied in a method for assembling an enclosure in a vehicle. The method includes forming the enclosure from an interior component of the vehicle. The enclosure includes a front section that defines an aperture and a rear section that defines a volume. The front and rear sections form an integrated component. The method also includes mechanically coupling a baffle to the enclosure. The baffle is located within a periphery of the aperture so as to form a port between the baffle and the enclosure. A transducer is mechanically coupled to the baffle. The port can be flared. A cross-sectional area of the port can vary along at least a portion of the length of the port to create at least one flare. The flare can be formed by varying a diameter of the baffle along a depth of the baffle. The flare can be formed by varying the diameter of the enclosure along a length that is adjacent to the baffle. A cross-sectional area of the port can be smoothly-varying or constantly-tapered along at least a portion of the length of the port.

In one embodiment, the rear section of the enclosure is formed using seamless construction. The interior component can be formed from multiple components. The method can also include forming a basket of the transducer from the baffle. The method can also include forming a plurality of ports around the peripheral edge of the baffle. In one embodiment, the interior component can include a door panel, a package shelf, an instrument panel, a dash board, a seatback, a seat, a visor, a console, headrest, headliner, cargo area lining, or a pillar garnish.

In another aspect, the invention is embodied in an enclosure for a vehicle. The enclosure includes a front section that defines an aperture for receiving a baffle. A rear section defines a volume. The front and rear sections are formed from an interior component of the vehicle. The baffle creates a port with the interior component.

The port can partially surround or completely surround a periphery of the baffle. The baffle can receive a transducer. In one embodiment, a cross-sectional area of the port varies along at least a portion of the length of the port to create at least one flare. The interior component can include a door panel, a package shelf, an instrument panel, a dash board, a seatback, a seat, a visor, a console, a headrest, a headliner, a cargo area lining, or a pillar garnish.

In another aspect, the invention is embodied in a baffle for a vehicle enclosure. The baffle includes an aperture for receiving a transducer. An outer edge of the baffle couples with the vehicle enclosure to create a port. The vehicle enclosure is formed from an interior component of the vehicle.

The port can partially surround or completely surround a periphery of the outer edge of the baffle. A cross-sectional area of the port can vary along at least a portion of the length of the port to create at least one flare. The interior component can be a door panel, a package shelf, an instrument panel, a dash board, a seatback, a seat, a visor, a console, a headrest, a headliner, a cargo area lining, or a pillar garnish.

### BRIEF DESCRIPTION OF THE DRAWINGS

This invention is described with particularity in the detailed description. The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1A is an exploded view of a transducer assembly having an enclosure with a port;

FIG. 1B is a perspective view of the transducer assembly of FIG. 1A;

FIG. 2A an exploded view of a transducer assembly having an enclosure with one radial port; and

FIG. 2B is a perspective view of the transducer assembly of FIG. 2A.

### DETAILED DESCRIPTION

A transducer assembly for a vehicle according to one embodiment of the invention includes an enclosure that is formed from a single piece of material. In one embodiment, the enclosure is fabricated without seams. The single piece of material can be an internal component of the vehicle. For example, the internal component can be a door panel, a package shelf, an instrument panel, a dashboard, a seat back, a seat, a headrest, a visor, a console, a headliner, a cargo area lining, or a pillar garnish that is located on a pillar in the vehicle, such as the front pillar, the middle pillar or the rear pillar. The single piece of material can be a metal material, a plastic material, an epoxy material, or any other suitable material. The enclosure can also be fabricated from multiple pieces of material. For example, a front section of the enclosure can be fabricated from a first piece of material and a rear section of the enclosure can be fabricated from a second piece of material.

The assembly includes at least one transducer. The transducer can be any shape or size. The transducer is coupled to a baffle. The baffle is mechanically coupled to the enclosure. In one embodiment, the baffle uniformly surrounds the transducer. The baffle can be integrated into the basket of the transducer.

In one embodiment, two or more transducers are coupled to a baffle. The baffle is coupled to an enclosure that is formed by techniques described herein. In one embodiment, each transducer is coupled to a dedicated volume. A dedicated volume is substantially acoustically coupled to a single port. Each port is formed by coupling the baffle to the enclosure. Thus, each port is acoustically coupled to a dedicated volume and can be tuned to a resonant frequency. The two ports can be tuned to different resonant frequencies.

In an embodiment including a single transducer coupled to a baffle, the enclosure can be a ported enclosure. The port can be formed from mating the baffle with the enclosure. The port can partially or substantially surround the baffle. The assembly can also include multiple ports. Each of the multiple ports can be a different shape and/or size. The combined ports have an effective cross section and length. For example, the enclosure can include a radial port that surrounds the baffle as well as a second port. The effective cross section and length of the combined ports along with the volume of the enclosure can be used to determine the resonance frequency of the combined ports.

One or more electronic components such as an amplifier and/or a cross-over network can be mounted inside the enclosure. Other circuitry such as an equalizer circuit can also be mounted inside the enclosure. Alternatively, the electronic components can be externally mounted.

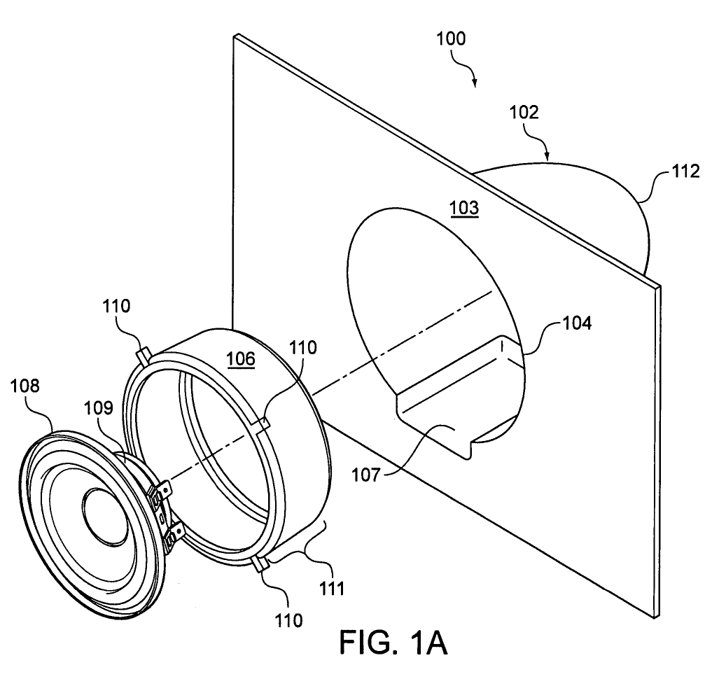

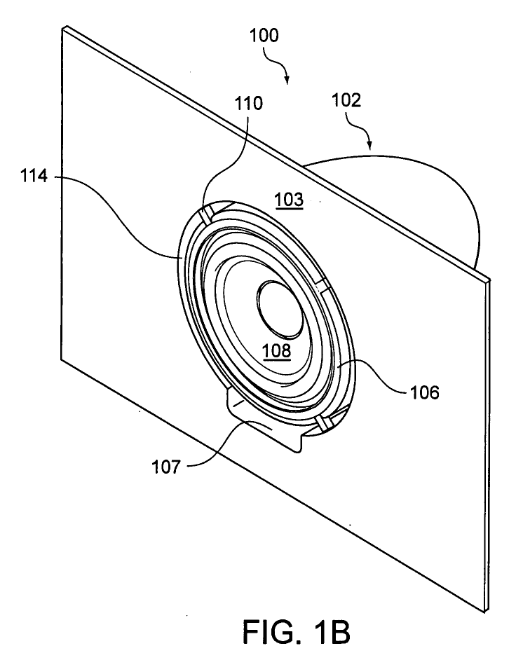

Referring to FIG. 1A, therein is shown an exploded view of a transducer assembly 100 having a port according to one embodiment of the invention. The assembly 100 includes an enclosure 102 having a front section 103 that defines an aperture 104. The aperture 104 is adapted to receive a baffle 106. The enclosure 102 is substantially bowl shaped and includes recess 107. The recess 107 is used to form a port that acoustically couples the volume of air captured by the enclosure 102 to the external atmosphere. The size and/or shape of the recess 107 can be adjusted to tune the port to different frequencies.

A transducer 108 can be coupled to the baffle 106. The transducer 108 can include a basket 109. The baffle 106 can uniformly surround the transducer 108. The baffle 106 can include mounting features 110 that align and/or secure the baffle 106 to the enclosure 102. The mounting features 110 can space the baffle 106 from the enclosure 102 forming a radial port around the baffle 106. This radial port co-acts with port formed from the recess 107 to create a combined port having an effective cross section and length that acoustically couples the interior volume of the enclosure 102 to the external atmosphere.

In one embodiment, the baffle 106 is sized to form a tight acoustic seal with the front section 103 of the enclosure 102 such that no gap exists between the baffle 106 and the front section 103, forming only a port from the recess 107 and no radial port.

In one embodiment, the baffle 106 is sized such that a small gap exists between the baffle 106 and the front section 103 of the enclosure 102. In this embodiment, the gap behaves like a radial port in the transducer assembly 100. Additionally, this configuration does not require an acoustic seal between the baffle 106 and the front section 103 of the enclosure. The radial port and the port formed from the recess 107 co-act to create a combined port having an effective cross section and length. The effective frequency of the combined port can be determined from the effective cross section and length of the combined port along with the enclosure volume.

The baffle 106 is coupled to the front section 103 of the enclosure 102 to form the port from the recess 107. The baffle 106 is sized to fit within the front section 103 of the enclosure 102. The depth 111, size and/or shape of the baffle 106 can be adjusted to tune the port to different frequencies. In one embodiment, tuning is accomplished by adjusting the relationship of the port acoustic mass to the acoustic compliance of the enclosure volume. For example, the mechanical dimensions of the port can be adjusted if the enclosure volume is optimized for a particular application. The cross sectional area and/or the length of the port can be varied to alter the acoustic mass of the port.

The enclosure 102 also includes a rear section 112 that defines a volume. The rear section 112 can be substantially bowl-shaped or any other suitable shape. The rear section 112 is formed from a single piece of material. For example, the single piece of material can be an interior component of the vehicle. As previously described, the interior component can be a door panel, a package shelf, an instrument panel, a dashboard, a seat back, a seat, a headrest, a visor, console, a headliner, a cargo area lining, or a pillar garnish, for example. The single piece of material can be a metal material, a plastic material, an epoxy material, a composite material, or any other suitable material. In addition, the material can be formed from a mold or fabricated by an injection molding technique. The enclosure 102 can also be formed of several individual components 103, 112 which are assembled to create a single integrated interior vehicle component.

The rear section 112 of the enclosure 102 can be formed using various techniques. For example, the single piece of material can be molded over a form having the desired shape to create the enclosure 102. In another embodiment, the single piece of material and the enclosure 102 can be manufactured using an injection molding process. Other known manufacturing techniques can also be used. The rear section 112 can be fabricated without seams.

The transducer assembly 100 can be assembled as follows. The following assembly process is an example of one method of assembly but other methods using different assembly steps can also be used. The interior component including the enclosure 102 can be initially mounted to the interior of the vehicle. The transducer 108 can be coupled to the baffle 106 using conventional mounting hardware. The baffle 106 can then be coupled to the enclosure 102 using conventional hardware, welding, snap/interference fit, or gluing techniques.

In one embodiment, an electronic device (not shown) such as, but not limited to, an amplifier, a crossover network, or an equalizer can be mounted inside the enclosure 102. The transducer 108 can be electrically coupled to the electronic device. In another embodiment, the electronic device can be remotely located from the enclosure 102. The transducer 108 can be coupled to the electronic device through signal transmission lines. In one embodiment (not shown), the enclosure 102 is designed to support multiple transducers. In another embodiment (not shown) multiple transducers can be coupled to a single baffle 106 or each transducer can be coupled to its own baffle. The multiple transducers can be coupled to a single volume. The signal volume can be acoustically coupled to a port. Alternatively, each of the multiple transducers can be coupled to a separate dedicated volume. Each dedicated volume can be acoustically coupled to a single port and can be tuned to a resonant frequency. The multiple ports can be tuned to different resonant frequencies.

FIG. 1B is a perspective view of the transducer assembly 100 of FIG. 1A in an assembled state. In one embodiment, the transducer 108 is positioned within the baffle 106. The baffle 106 is positioned to be substantially flush against the front section 103. A grill (not shown) can be positioned over the transducer 108. The grill can be fabricated from a metal mesh, fabric or any suitable material.

In one embodiment, the combination of the baffle 106 and the recess 107 form a port in the enclosure 102. The port can include a flare. A flare varies the cross sectional area of the port. The flare can vary the cross sectional area along the entire length of the port or any portion of the length of the port. The flare can smoothly vary cross sectional area and/or can have a constant taper. The port can have flares on one or both ends of the port. For example, the flare can be initiated inside the enclosure continue to the input or the output of the port. In one embodiment, the recess 107 includes a flared segment proximate to the front section 103. The flared segment can also be located in the rear section 112 of the enclosure 102, the diameter of the flare can be varied along any portion of the length of the enclosure 102 starting at the aperture and continuing into the rear section 112 of the enclosure 102 to a location corresponding to the depth 111 of the baffle 106. The flare can be formed in or integrated with the baffle 106. The flare can improve the acoustic properties of the port.

As previously described, the baffle 106 can form a radial port 114 that is located within the periphery of the aperture 104 (FIG. 1A). The dimensions of the radial port can be adjusted to tune the port. For example, the diameter of the aperture in the front section 103 and/or the diameter of the baffle 106 can be adjusted to vary the cross-sectional area of the port. Other dimensions of the enclosure 102 and/or the baffle 106 can also be adjusted to tune the port. Additionally, the radial port can be flared. The flare can be located on the input and/or the output of the radial port. The flare can be formed in the front section 103 and/or the baffle 106.

In one embodiment, one or both ends of the port are flared by varying the inner diameter of the enclosure 102 and/or the outer diameter of the baffle as a function of the length of the port. A description of port configurations can be found in U.S. Pat. No. 5,714,721 entitled “Porting”, the entire disclosure of which is incorporated herein by reference.

In one embodiment, the basket 109 (FIG. 1A) of the transducer 108 is formed from the baffle 106. The baffle 106 can be fabricated from a metal material, a plastic material, an epoxy material or any other suitable material.

In one embodiment, the baffle 106 is integrated with the enclosure 102. For example, the baffle 106 and the enclosure 102 can be formed from a single component or can be formed from multiple components. In one embodiment, the transducer 108 is mounted to the front surface of the baffle 106. The transducer 108 can be mounted to the baffle 106 using conventional hardware, locking tabs, glue, or snap/interference fit, for example.

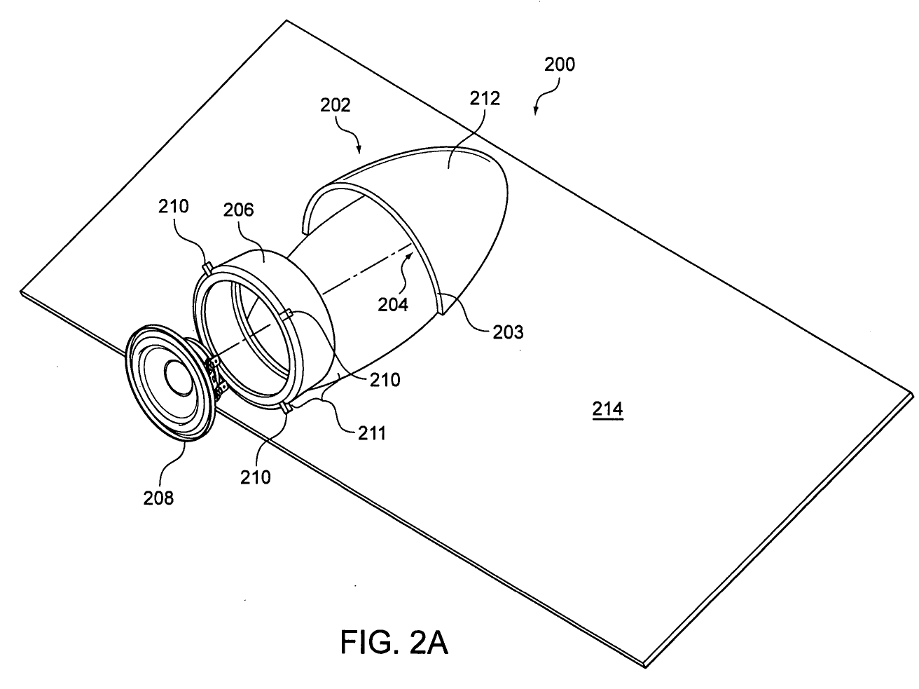

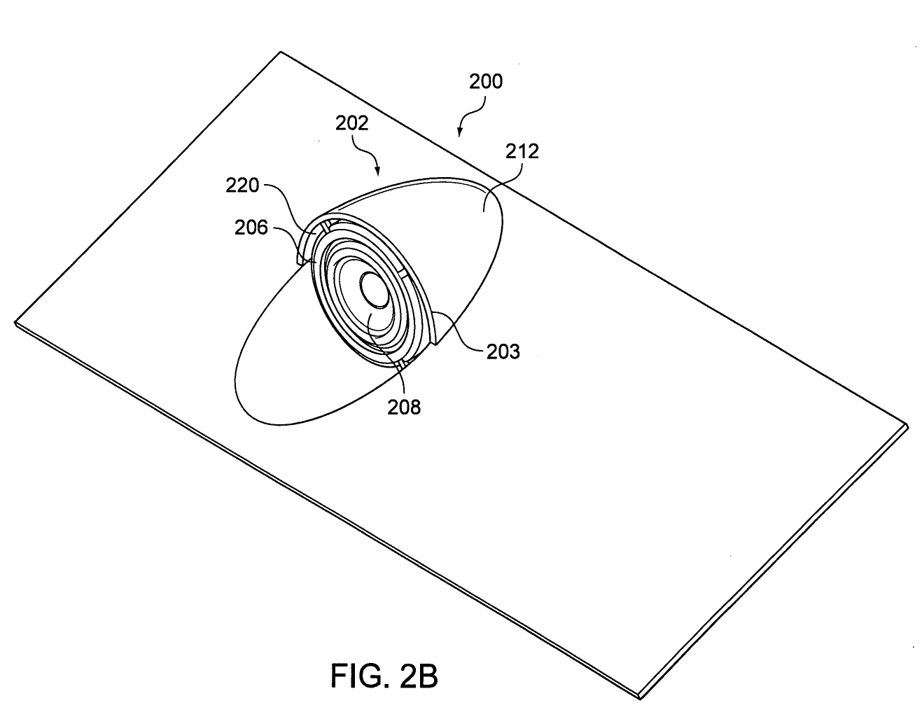

FIG. 2A an exploded view of a transducer assembly 200 having a single port according to another embodiment of the invention. The transducer assembly 200 includes an enclosure 202 having a front section 203 that defines an aperture 204. The aperture 204 is adapted to receive a baffle 206. A transducer 208 can be coupled to the baffle 206. The baffle 206 can include mounting features 210 that align and/or secure the baffle 206 to the enclosure 202. The mounting features 210 can space the baffle 206 from the enclosure 202 forming a radial port around the baffle 206 that acoustically couples the interior volume of the enclosure 202 to the external atmosphere. The enclosure 202 can be substantially bowl shaped. The baffle 206 is sized to fit within the front section 203 of the enclosure 202. The depth 211 of the baffle 206 is sized to define the length of the port.

The enclosure 202 also includes a rear section 212 that defines a volume. The rear section 212 can be substantially bowl-shaped or any other suitable shape. The rear section 212 can be formed from a single piece of material 214. For example, the single piece of material 214 can be an interior component of the vehicle. In this configuration, the interior component of the vehicle can be a rear package shelf or the top surface of a dashboard, for example. The enclosure 202 is shaped so as to direct acoustic radiation from the transducer 208 substantially perpendicular to the single piece of material 214. In practice, the transducer 208 can be positioned to direct acoustic radiation at any desired angle.

As previously described, the single piece of material 214 can be a metal material, a plastic material, a composite material, an epoxy material, or any other suitable material. The enclosure 202 can be formed into any desired shape. In addition, any desired angle can be formed between the plane of the aperture 204 of the front section 203 of the enclosure 202 and the top surface of the single piece of material 214. The enclosure 202 can also be formed of several individual components 214, 212 which are assembled to create a single integrated interior vehicle component.

The rear section 212 of the enclosure 202 can be formed using various techniques. For example, the single piece of material 214 can be molded over a form having the desired shape to create the enclosure 202. In another embodiment, the single piece of material 214 and the enclosure 202 can be manufactured using an injection molding process. Other known manufacturing techniques can also be used. The rear section 212 can be fabricated without seams.

FIG. 2B is a perspective view of the transducer assembly 200 of FIG. 2A in an assembled state. In one embodiment, the transducer 208 is positioned within the baffle 206. The baffle 206 is positioned to be substantially within the aperture of the front section 203 of the enclosure 202. A grill (not shown) can be positioned over the transducer 208. The grill can be fabricated from a metal mesh, fabric or any suitable material.

In one embodiment, the basket of the transducer 208 can be formed from the baffle 206. The baffle 206 can be fabricated from a metal material, a plastic material, an epoxy material, or any other suitable material.

In one embodiment, the baffle 206 is integrated with the enclosure 202. For example, the baffle 206 and the enclosure 202 can be formed from a single component or can be formed from multiple components. In this embodiment, the transducer 208 is mounted to the front surface of the baffle 206. The transducer 208 can be mounted to the baffle 206 using conventional hardware, locking tabs, snap/interference fit, or glue, for example.

The transducer assembly 200 includes a port 220 that completely surrounds a periphery of the baffle 206. As previously described, the port 220 can be a flared port, in which the flare is formed from the baffle 206 and/or the enclosure 202. In one embodiment, the transducer assembly 200 includes a port (not shown) that can be located proximate to the periphery of the baffle 206. The port can be formed to create any desired cross-sectional area and resonant frequency.

While the invention has been particularly shown and described with reference to specific exemplary embodiments, it is evident that those skilled in the art may now make numerous modifications of, departures from and uses of the specific apparatus and techniques herein disclosed. Consequently, the invention is to be construed as embracing each and every novel feature and novel combination of features presented in or possessed by the apparatus and techniques herein disclosed and limited only by the spirit and scope of the appended claims.

What is claimed is:

1. An enclosure for a transducer comprising:
a front section defining an aperture;
a rear section defining a volume, the front and rear sections forming a component; and
a baffle that is located within a periphery of the aperture so as to form a port between the baffle and the component.

2. The enclosure of claim 1 wherein the port completely surrounds a periphery of the baffle.

3. The enclosure of claim 1 wherein a cross-sectional area of the port varies along at least a portion of the length of the port to create at least one flare.

4. The enclosure of claim 3 wherein the flare is formed by varying a diameter of the baffle along a depth of the baffle.

5. The enclosure of claim 3 wherein the flare is formed by varying the diameter of the component along a length that is adjacent to the baffle.

6. The enclosure of claim 3 wherein the cross-sectional area of the port is smoothly-varying along at least a portion of the length of the port.

7. The enclosure of claim 3 wherein the cross-sectional area of the port is constantly-tapered along at least a portion of the length of the port.

8. The enclosure of claim 1 wherein the rear section of the enclosure is substantially bowl-shaped.

9. The enclosure of claim 1 wherein the port at least partially surrounds a periphery of the baffle.

10. The enclosure of claim 1 further comprising a plurality of ports disposed around a periphery of the baffle.

11. The enclosure of claim 10 wherein at least two of the plurality of ports comprise unequal cross-sectional areas.

12. The enclosure of claim 1 wherein the rear section of the enclosure is formed from an interior component of the vehicle.

13. The enclosure of claim 12 wherein the interior component is chosen from the group comprising a door panel, a package shelf, an instrument panel, a dash board, a seatback, a seat, a visor, a console, a headrest, a headliner, a cargo area lining, and a pillar garnish.

14. The enclosure of claim 1 wherein the component is fabricated using seamless construction.

15. The enclosure of claim 1 wherein the component comprises multiple components that are integrated together.

16. The enclosure of claim 1 wherein a basket of the transducer is formed from the baffle.

17. The enclosure of claim 16 wherein the basket of the transducer is fabricated from plastic material.

18. The enclosure of claim 1 wherein the front section of the enclosure is fabricated from a plastic material.

19. The enclosure of claim 1 wherein the transducer is mechanically coupled to the baffle.

20. A transducer assembly for a vehicle comprising:
an enclosure formed from an interior component of the vehicle, the enclosure comprising a front section defining an aperture and a rear section defining a volume;
a baffle that is located within a periphery of the aperture so as to form a port between the baffle and the enclosure; and
a transducer that is mechanically coupled to the baffle.

21. The transducer assembly of claim 20 wherein the port completely surrounds a periphery of the baffle.

22. The transducer assembly of claim 20 wherein a cross-sectional area of the port varies along at least a portion of the length of the port to create at least one flare.

23. The transducer assembly of claim 22 wherein the flare is formed by varying a diameter of the baffle along a depth of the baffle.

24. The transducer assembly of claim 22 wherein the flare is formed by varying the diameter of the enclosure along a length that is adjacent to the baffle.

25. The transducer assembly of claim 22 wherein the cross-sectional area of the port is smoothly-varying along at least a portion of the length of the port.

26. The transducer assembly of claim 22 wherein the cross-sectional area of the port is constantly-tapered along at least a portion of the length of the port.

27. The transducer assembly of claim 20 wherein the rear section of the enclosure is substantially bowl-shaped.

28. The transducer assembly of claim 20 wherein the port at least partially surrounds a periphery of the baffle.

29. The transducer assembly of claim 20 further comprising a plurality of ports disposed around a periphery of the baffle.

30. The transducer assembly of claim 29 wherein at least two of the plurality of ports comprise unequal cross-sectional areas.

31. The transducer assembly of claim 20 wherein the interior component is chosen from the group comprising a door panel, a package shelf, an instrument panel, a dash board, a seatback, a seat, a visor, a console, a headrest, a headliner, a cargo area lining, and a pillar garnish.

32. The transducer assembly of claim 20 wherein the interior component comprises multiple components that are integrated together.

33. The transducer assembly of claim 20 wherein the interior component is fabricated using seamless construction.

34. The transducer assembly of claim 20 wherein a basket of the transducer is formed from the baffle.

35. The transducer assembly of claim 34 wherein the basket of the transducer is fabricated from plastic material.

36. The transducer assembly of claim 20 wherein the front section of the enclosure is fabricated from a plastic material.

37. The transducer assembly of claim 20 wherein the baffle is integrated with the enclosure.

38. A method for assembling an enclosure in a vehicle, the method comprising:
forming the enclosure from an interior component of the vehicle, the enclosure comprising a front section defining an aperture and a rear section defining a volume;
mechanically coupling a baffle to the enclosure, the baffle being located within a periphery of the aperture so as to form a port between the baffle and the enclosure; and
mechanically coupling a transducer to the baffle.

39. The method of claim 38 wherein the rear section of the enclosure is formed using seamless construction.

40. The method of claim 38 wherein the interior component is formed from multiple components that are integrated together.

41. The method of claim 38 wherein a cross-sectional area of the port varies along at least a portion of the length of the port to create at least one flare.

42. The method of claim 41 wherein the flare is formed by varying a diameter of the baffle along a depth of the baffle.

43. The method of claim 41 wherein the flare is formed by varying the diameter of the enclosure along a length that is adjacent to the baffle.

44. The method of claim 41 wherein the cross-sectional area of the port is smoothly-varying along at least a portion of the length of the port.

45. The method of claim 41 wherein the cross-sectional area of the port is constantly-tapered along at least a portion of the length of the port.

46. The method of claim 38 further comprising forming a basket of the transducer from the baffle.

47. The method of claim 38 further comprising forming a plurality of ports around the peripheral edge of the baffle.

48. The method of claim 38 wherein the interior component is chosen from the group comprising a door panel, a package shelf, an instrument panel, a dash board, a seatback, a seat, a visor, a console, a headrest, a headliner, a cargo area lining, and a pillar garnish.

49. An enclosure for a vehicle comprising:
a front section defining an aperture for receiving a baffle; and
a rear section defining a volume, the front and rear sections being formed from an interior component of the vehicle, the baffle creating a port with the interior component.

50. The enclosure of claim 49 wherein the port at least partially surrounds a periphery of the baffle.

51. The enclosure of claim 49 wherein the baffle is adapted to receive a transducer.

52. The enclosure of claim 49 wherein a cross-sectional area of the port varies along at least a portion of the length of the port to create at least one flare.

53. The enclosure of claim 49 wherein the interior component is chosen from the group comprising a door panel, a package shelf, an instrument panel, a dash board, a seatback, a seat, a visor, a console, a headrest, a headliner, a cargo area lining, and a pillar garnish.

54. A baffle for a vehicle enclosure comprising:
an aperture for receiving a transducer; and
an outer edge that couples with the vehicle enclosure to create a port, the vehicle enclosure being formed from an interior component of the vehicle.

55. The baffle of claim 54 wherein the port at least partially surrounds a periphery of the outer edge.

56. The baffle of claim 54 wherein a cross-sectional area of the port varies along at least a portion of the length of the port to create at least one flare.

57. The baffle of claim 54 wherein the interior component is chosen from the group comprising a door panel, a package shelf, an instrument panel, a dash board, a seatback, a seat, a visor, a console, a headrest, a headliner, a cargo area lining, and a pillar garnish.

58. A transducer assembly for a vehicle comprising:
means for forming the enclosure from an interior component of the vehicle, the enclosure comprising a front section defining an aperture and a rear section defining a volume;
means for mechanically coupling a baffle to the enclosure, the baffle being located within a periphery of the aperture so as to form a port between the baffle and the enclosure; and
means for mechanically coupling a transducer to the baffle.
